(19) United States
(12) Patent Application Publication
(10) Pub. No.: US 2006/0081856 A1
(43) Pub. Date: Apr. 20, 2006

(54) Novel wide bandgap material and method of making

(76) Inventors: Narsingh B. Singh, Ellicott City, MD (US); Andre Berghmans, Owings Mills, MD (US); Tracy Ann Waite, Owings Mills, MD (US); Michael Aumer, Columbia, MD (US); Hong Zhang, Gambrills, MD (US); Darren Thomson, Ellicott City, MD (US); David Kahler, Arbutus, MD (US); Abigail Kirschenbaum, Silver Spring, MD (US)

Correspondence Address: BIRCH STEWART KOLASCH & BIRCH, PO BOX 747, FALLS CHURCH, VA, 22040-0747, US

(21) Appl. No.: 10/965,840

(22) Filed: Oct. 18, 2004

(51) Int. Cl. H01L 31/0312

(52) U.S. Cl. 257/77

(57) ABSTRACT

A wide bandgap semiconductor material comprised of Silicon carbide containing a predetermined portion of germanium.

### BACKGROUND OF THE INVENTION

1. Field of the Invention

The invention in general relates to semiconductors and more particularly to a semiconductor material having a wide bandgap and high mobility.

2. Description of Related Art

SiC (silicon carbide) is a wide bandgap semiconductor having excellent properties for high power applications such as in power generation, power distribution, switches, filters, and broadband power RF transmitters, to name a few. Devices of SiC exhibit high efficiency, high linearity as well as low noise and are operable at x-band (around 8-12 GHz) in addition to Ku-band (12-18 GHz) and Ka-band (27-40 GHz).

A wide bandgap semiconductor (bandgap energy ≧2 eV) in general exhibits desirable thermal properties, has high power capability, radiation insensitivity with high temperature high frequency and low noise operation. Although other semiconductor materials may exhibit a higher bandgap value than SiC, SiC has a relatively higher mobility than these other materials. Mobility basically is an indication of charge carrier (holes or electrons) scattering. In a high mobility semiconductor these charge carriers move with less scattering resulting in a higher current per unit of electric field.

It is a primary object of the present invention to provide a novel SiC-based semiconductor with higher a higher bandgap and higher mobility than conventional SiC.

### SUMMARY OF THE INVENTION

A wide bandgap semiconductor material is fabricated and is comprised of Silicon carbide containing a predetermined portion of germanium. With the wide bandgap semiconductor material having a formula of Si₍₁₋ₓ₎Ge₍ₓ₎C, 0<x≦0.05. The material is preferably grown by the physical vapor transport process.

Further scope of applicability of the present invention will become apparent from the detailed description provided hereinafter. It should be understood, however, that the detailed description and specific example, while disclosing the preferred embodiment of the invention, is provided by way of illustration only, since various changes and modifications within the spirit and scope of the invention will become apparent to those skilled in the art, from the detailed description.

### BRIEF DESCRIPTION OF THE DRAWINGS

The present invention will become more fully understood from the detailed description provided hereinafter and the accompanying drawing, which is not necessarily to scale, and is given by way of illustration only, and wherein:

FIG. 1 is a simplified presentation of a PVT growth system.

### DESCRIPTION OF THE PREFERRED EMBODIMENT

The novel wide bandgap material of the present invention may be fabricated by a number of well-known processes, however it will be described, by way of example, with respect to the PVT (physical vapor transport) growth process.

Basically, In the PVT process, a seed crystal of silicon carbide is positioned within a furnace system which also includes a source, or feedstock, generally in powder form. The feedstock is heated to a particular temperature, with the seed crystal maintained at a different, and lower, temperature whereby the silicon carbide sublimes, forming various molecular species such as Si, Si₂C and SiC₂. As a result of this, silicon carbide is deposited upon the seed crystal, forming and growing a boule. After the boule is grown to a desired size, it is removed from the furnace system and then prepared and sliced into wafers which may be used as semiconductor device substrates.

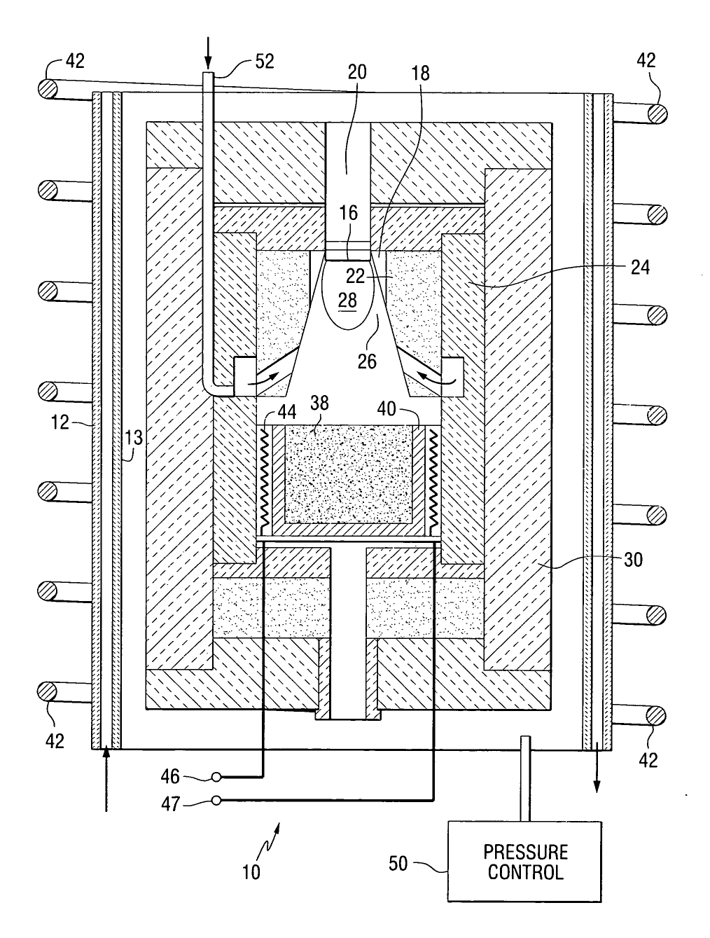

FIG. 1 shows, in rudimentary form, a typical apparatus for growing silicon carbide boules by the aforementioned PVT method. The apparatus includes a furnace system 10 having a vacuum tight enclosure formed by coaxial quartz cylinders 12 and 13, with a cooling water flow between them. A silicon carbide seed crystal 16 is mounted on a seed holder 18 having a hollow portion 20 directly behind the seed crystal 16 for cooling purposes.

A crystal growth structure surrounds the seed crystal 15 and includes a porous graphite wall 22 surrounded by a graphite susceptor 24 and defining an interior growth cavity 26 for boule 28. A thermal insulation 30 surrounds the components.

Disposed axially below seed crystal 16 is a feedstock 38, containing silicon carbide powder, within feedstock container 40. In the present invention germanium is also added to the feedstock in the proportion of around 1:1 for growing a silicon germanium carbide boule 28 of a composition Si₍₁₋ₓ₎Ge₍ₓ₎C, where 0<x≦0.05. The required temperature for growth of the resulting silicon germanium carbide boule 28 is provided by a heating system such as an RF coil 42, which may be inside or outside of the enclosure formed by cylinders 12 and 13. In addition, feedstock container 40, and its contents, may also be heated by a resistance, or ladder heater 44, which surrounds the container 40 and is supplied with electrical energy at terminals 47 and 47.

To grow the silicon germanium carbide boule 28, the silicon carbide seed crystal 16 and silicon carbide/germanium feedstock 38 are placed in position surrounded by the thermal insulation 30 and the furnace system is brought down to a near vacuum pressure of, for example, 10⁻⁷ Torr by means of pressure control unit 50. The heater system is then activated to drive off any adsorbed gases in order to reduce any electrically active impurities which may be present. The interior pressure is then increased to near atmospheric pressure and then reduced to operating pressure and the temperatures for boule growth are established.

It is conventional to provide the interior of the furnace system 10 with an inert gas such as argon or nitrogen to maintain pressure conditions. This gas is introduced via gas passageway 52 leading into the furnace interior.

Actual SiGeC boules have been fabricated using the PVT growth process described herein and as an added advantage it has been determined that undesired micropipe defects which may be present in conventional SiC boule growth have been significantly reduced, if not eliminated. In addition the tendency to grow more than one desired polytype crystal has also been significantly reduced.

A typical PVT-type SiGeC boule grown as described herein was determined to have a bandgap of around 3.68 eV with a mobility of 110 cm²/Vs. Growth parameters included:

Operating pressure: −20 Torr in an Argon atmosphere

Source temperature: −2190° C.

ΔT between source and seed: −80° C.

Amount of SiC: −11.9 gms

Amount of Ge: −10.2 gms

Growth time: −66 hrs

Length of resulting boule: −7 mm

It is to be noted that although almost equal amounts of SiC and Ge are used, most of the vaporized Ge exits the system via a path including the pressure control unit 50 and very little Ge is incorporated in the growing boule 28. Accordingly, in the formula Si₍₁₋ₓ₎Ge₍ₓ₎C. for the resulting boule, the average x was determined to be around 0.04 (4%).

Although a preferred method of fabrication of the SiGeC material is the described PVT process, other processes are also possible. For example the material may be made by the CVD (chemical vapor deposition) process or the MOCVD (metal organic chemical vapor deposition) process using (CH₃)₆Si₂ (hexamethyldisilane) and GeH₄ (germain gas).

The foregoing detailed description merely illustrates the principles of the invention. It will thus be appreciated that those skilled in the art will be able to devise various arrangements which, although not explicitly described or shown herein, embody the principles of the invention and are thus within its spirit and scope.

What is claimed is:

1. A wide bandgap semiconductor material, comprising:
Silicon carbide containing a predetermined portion of germanium.

2. A wide bandgap semiconductor material according to claim 1 wherein:
the formula for said wide bandgap semiconductor material is Si₍₁₋ₓ₎Ge₍ₓ₎C; and
where 0<x≦0.05.

3. A method of making a wide bandgap semiconductor material, comprising the steps of:
growing a Silicon carbide structure by a predetermined growth process;
adding a predetermined amount of germanium to said growth process.

4. A method according to claim 3 which includes:
growing said silicon carbide structure as a boule by the physical vapor transport process.
